(19) United States
(12) Patent Application Publication
(10) Pub. No.: US 2009/0017258 A1
(43) Pub. Date: Jan. 15, 2009

(54) DIAMOND FILM DEPOSITION

(76) Inventors: John A. Carlisle, Plainfield, IL (US); Charles F. West, Chicago, IL (US); Jerry W. Zimmer, Saratoga, CA (US)

Correspondence Address: FOLEY AND LARDNER LLP;SUITE 500, 3000 K STREET NW, WASHINGTON, DC, 20007, US

(21) Appl. No.: 11/775,846

(22) Filed: Jul. 10, 2007

(51) Int. Cl. B32B 5/16; C23C 16/27

(52) U.S. Cl. 428/143; 427/249.8

(57) ABSTRACT

Diamond material made by a hot filament chemical vapor deposition process, providing large film area, good growth rate, phase purity, small average grain size, smooth surfaces, and other useful properties. Low substrate temperatures can be used. Control of process variables such as pressure and filament temperature and reactant ratio allow control of the diamond properties. Applications include MEMS, wear resistance low friction coatings, biosensors, and electronics.

### BACKGROUND

Diamond is an important luxury and industrial material which nature provides and also now can be made synthetically. Whether it is natural or synthetic, diamond is actually a family of materials, and some forms of diamond are more useful than other forms for particular applications as the properties of the different forms vary. Types of diamond known in the art include, for example, microcrystalline diamond (MCD), nanocrystalline diamond (UNCD), and ultrananocrystalline diamond (UNCD). Diamond can comprise a plurality of individual grains of diamond, and the size of the grains can vary. In many cases, it is desirable to control the form or the morphology of the diamond down to smaller and smaller scales, including down to the nanoscale, so as to obtain the best properties. Diamond can be an expensive material, and the cost of different diamond forms can vary. Hence, for commercialization, it is important to better understand how to synthesize diamond with better properties and cost-benefits under commercially realistic conditions. See, for example, Synthesis, Properties, and Applications of Ultrananocrystalline Diamond, 2005; Handbook of Industrial Diamonds and Diamond Films, 1998.

One method to make diamond is chemical vapor deposition (CVD). In this method, a chemical vapor can be reacted over a solid surface, and the result is the formation or deposition of a material on the solid surface. For example, one can react in a CVD reaction chamber multiple components including for example (i) a compound comprising carbon with (ii) hydrogen gas to form diamond on a solid surface. Or one can react a compound comprising carbon in the presence of a noble gas to form diamond on a solid surface. One can use a hot surface or plasmas to activate reaction. In recent years, much interest has arisen in use of noble gases in the diamond deposition because the type of diamond made from these processes, sometimes called UNCD, can provide advantages including very smooth as-deposited surfaces, high hardness, have small particle grain sizes, low deposition temperatures, the ability to pattern to nanoscale resolution including use of self-aligned deposition, and other useful properties. Useful properties can be, for example, mechanical, tribological, transport, electrochemical, or electron emission in nature. See, for example, U.S. Pat. No. 7,128,889 (Carlisle et al.) and U.S. Pat. No. 5,849,079 and publication no. 2005/0031785 (Carlisle et al).

However, while CVD can be a successful method for research in diamond science, commercial production can provide demands which are not addressed by academic research. Therefore, despite these advances, a need exists to develop methods of synthetic diamond production for commercial applications, including UNCD production, which are more amenable to, for example, deposition over larger surface areas, use of multiple substrates, faster deposition rates, deposition with good uniformity, and deposition at lower temperatures.

### SUMMARY

One embodiment provides a method comprising: providing at least one hot filament chemical vapor deposition reaction chamber, providing at least one substrate in the reaction chamber, providing at least one vapor to the reaction chamber, wherein the vapor provided to the reaction chamber comprises (i) a compound comprising carbon, and (ii) hydrogen, and wherein the vapor is substantially free of noble gas and inert gas, reacting the vapor in the reaction chamber so that a diamond material is deposited on the substrate, wherein the reacting step is carried out at a pressure of less than about 10 torr, and a filament temperature of at least about 2350° C.

Another embodiment provides a method comprising: providing at least one hot filament chemical vapor deposition reaction chamber, providing at least one substrate in the reaction chamber, providing at least one vapor to the reaction chamber, wherein the vapor provided to the reaction chamber comprises (i) a compound comprising carbon, and (ii) hydrogen, and wherein the vapor is substantially free of noble gas and inert gas, reacting the vapor in the reaction chamber so that a diamond material is deposited on the substrate, wherein the reacting step is carried out at a pressure and a filament temperature to produce diamond material characterized by: an average grain size of about 10 nm or less, a roughness average for the as-deposited film of about 20 nm or less, and a ratio of sp²- to sp³-bonded carbon of about 5% or less.

Another embodiment provides an article comprising: a substrate, at least one single diamond film disposed on the substrate, wherein the area of the single diamond film is at least 8,000 square mm and the single diamond film is characterized by an average grain size of about 10 nm or less, a roughness average for the as-deposited film of about 20 nm or less, and a ratio of sp²- to sp³-bonded carbon of about 5% or less.

Another embodiment provides a method comprising: providing at least one hot filament chemical vapor deposition reaction chamber, providing at least one substrate in the reaction chamber, the substrate having a surface area of at least 8,000 square mm, providing at least one vapor to the reaction chamber, wherein the vapor provided to the reaction chamber comprises (i) a compound comprising carbon, and (ii) hydrogen, and wherein the vapor is substantially free of noble gas and inert gas, reacting the vapor in the reaction chamber so that a diamond material is deposited on the substrate, wherein the reacting step is carried out at a pressure of less than about 10 torr, and a filament temperature of at least about 2350° C., wherein the diamond material characterized by: an average grain size of about 10 nm or less, a roughness average for the as-deposited film of about 20 nm or less, and a ratio of sp²- to sp³-bonded carbon of about 5% or less.

Another embodiment provides a method comprising: providing at least one hot filament chemical vapor deposition reaction chamber comprising a hot filament, providing at least one substrate in the reaction chamber, wherein the substrate is held by a substrate holder which is adapted to heat and cool the substrate and orient the substrate position with respect to the hot filament, providing flow of vapor to the reaction chamber, wherein the vapor provided to the reaction chamber comprises (i) a compound comprising carbon, and (ii) hydrogen, and wherein the vapor is substantially free of noble gas and inert gas, reacting the vapor in the reaction chamber so that a diamond material is deposited on the substrate, wherein the reacting step is carried out at a pressure of less than about 10 torr, and a filament temperature of at least about 2,350° C., and wherein the reacting step is carried out at a substrate temperature of about 600° C. or less.

Another embodiment provides a method comprising: providing at least one hot filament chemical vapor deposition reaction chamber, providing at least one substrate in the reaction chamber, providing at least one vapor to the reaction chamber, wherein the vapor provided to the reaction chamber comprises (i) a compound comprising carbon, and (ii) hydrogen, and wherein the vapor is substantially free of noble gas and inert gas, reacting the vapor in the reaction chamber so that a diamond material comprising ultrananocrystalline diamond is deposited on the substrate, wherein the reacting step is carried out at a pressure of less than about 10 torr, and a filament temperature of at least about 2,350° C.

Various embodiments described herein include methods of making compositions, compositions, methods of using compositions, and devices comprising compositions.

One or more advantages of one or more of the embodiments described herein include, for example, diamond films having desirable crystal structure, crystal size, smoothness, and uniformity. Diamond can be made at good deposition rates at relatively lower temperatures. One can make highly desirable diamond films over large surface areas, including a plurality of films on different substrates, larger than what can be achieved in prior art methods for making high quality, phase pure ultrananocrystalline diamond (UNCD). Furthermore, one does not need to provide the reaction chamber with a microwave plasma. The relative cost and complexity of a hot-filament technology is considerably less compared to microwave-based technologies.

### BRIEF DESCRIPTION OF THE FIGURES

FIG. 1. (a) general schematic of the HFCVD deposition apparatus highlighting some of the principal species theorized to be responsible for UNCD deposition; (b) Image of the deposition chamber showing tungsten filaments above several single crystal Si substrates.

FIG. 2. Scanning Electron Micrographs, Raman spectra and deposition parameters for Run #21 (MCD).

FIG. 3. Scanning Electron Micrographs, Raman spectra and deposition parameters for Run #22 (MCD).

FIG. 4. Scanning Electron Micrographs, Raman spectra and deposition parameters for Run #32 (UNCD).

FIG. 5. Scanning Electron Micrographs, Raman spectra and deposition parameters for Run #41 (MCD).

FIG. 6. Scanning Electron Micrographs, Raman spectra and deposition parameters for Run #43 (MCD).

FIG. 7. Scanning Electron Micrographs, Raman spectra and deposition parameters for Run #47 (NCD).

FIG. 8. Scanning Electron Micrographs, Raman spectra and deposition parameters for Run #49 (NCD+MCD).

FIG. 9. Scanning Electron Micrographs, Raman spectra and deposition parameters for Run #50 (NCD).

FIG. 10. AFM Data of representative UNCD film grown on clean Si substrate (Avg. Ra=11.8 nm).

FIG. 11. High Resolution Transmission Electron Micrograph (HRTEM) of representative UNCD film.

FIG. 12. Grain size distribution of representative UNCD from HRTEM (Avg. grain size=6 nm).

FIG. 13. Near Edge X-Ray Absorption Fine Structure (NEXAFS) spectrum of representative UNCD film showing a preponderance of sp3-bonded carbon (290 eV) as compared to π-bonded carbon at ˜285 eV (the integrated areas of these two peaks, i.e. 290 eV and 285 eV is proportional to the relative concentration of sp3 and sp2 bonded carbon, respectively).

FIG. 14. Membrane Defect Analysis of ˜150 nm long cantilevers coated with representative UNCD film showing a Young's Modulus of ˜800 GPa.

FIG. 15. Raman spectrum of a representative UNCD film deposited at a substrate temperature of 600° C.

FIG. 16. NEXAFS spectrum of a representative UNCD film grown at a substrate temperature of 600° C. compared with a NEXAFS spectrum of a single crystal diamond reference sample showing the near absence of sp2 carbon in both (285 eV region of the spectrum).

FIG. 17. Raman spectrum of a representative UNCD film deposited at a substrate temperature of 350° C. using a water-cooled substrate holder to maintain the deposition temperature.

FIG. 18. NEXAFS spectrum of a representative UNCD film grown at a substrate temperature of 350° C.

FIG. 19 provides a summary of process conditions and surface characterization data for diamond deposition experiments. Column headings are provided below.

FIG. 20 provides (a) SEM image of five diamond membranes showing characteristic geometries, (b) photograph of the test setup.

FIG. 21 provides a schematic drawing of the MDE setup and monochromatic images of the bottom side of the membranes showing an unloaded membrane (a) and a membrane under load which has developed fringes (b).

### DETAILED DESCRIPTION

### Introduction

References cited herein are hereby incorporated by reference in their entirety.

The following references, and other references cited herein, can be used as needed in practice of the various embodiments described herein:

May et al. “Reevaluation of the mechanism for ultrananocrystalline diamond deposition from Ar/CH4/H2 gas mixtures”, Journal of Applied Physics, 99, 104907 (2006);

May et al. “Experiment and modeling of the deposition of ultrananocrystalline diamond films using hot filament chemical vapor deposition and Ar/CH4/H2 gas mixtures: A generalized mechanism for ultrananocrystalline diamond growth.” J. Applied Phys., 100, 024301 (2006).

May et al. “Microcrystalline, nanocrystalline and ultrananocrystalline diamond chemical vapor deposition: Experiment and modeling of the factors controlling growth rate, nucleation and crystal size”, Journal of Applied Physics, 101, 053115 (2007);

Gruen, “Nanocrystalline Diamond Films,” Annu. Rev. Mater. Sci., 29 (1999) 211.

Wang et al., “The fabrication of nanocrystalline diamond films using hot filament CVD”, Diamond Relat. Mater, 13-1, 6-13 (2004);

Xiao et al., “Low Temperature Growth of Ultrananocrystalline Diamond”, Journal of Applied Physics, 96, 2232 (2004);

Carlisle et al., “Characterization of nanocrystalline diamond films by core-level photoabsorption”, Appl. Phys. Lett 68, 1640 (1996);

Schwarz, et al., “Dependence of the growth rate, quality, and morphology of diamond coatings on the pressure during the CVD-process in an industrial hot-filament plant”, Diamond Rel. Materials., 11, 589 (2002);

James Birrell et al., Morphology and Electronic Structure of Nitrogen-doped Ultrananocrystalline Diamond Appl. Phys. Lett 81, 2235 (2002);

Birrell et al., Interpretation of the Raman Spectra of Ultrananocrystalline Diamond, Diamond & Relat. Mater. 14, 86 (2005);

Carlisle et al., Chemical Physics Letters, v. 430, iss. 4-6, p. 345-350;

Espinosa et al., Mechanical Properties of Ultrananocrystalline Diamond Thin Films Relevant to MEMS Devices, Exper. Mech. 43, (3), 256-268 (2003);

### Instrumentation: HFCVD Reaction Chamber

Hot filament chemical vapor deposition reaction chambers, and uses thereof, are known in the art. See for example U.S. Pat. Nos. 5,424,096; 5,939,140; 6,533,831; 5,160,544; 5,833,753; and May et al. J. Applied Phys, 100, 024301 (2006); Wang et al., Diamond Relat. Mater., 13-1, 6-13 (2004) (see also commercial products from sp3, Inc, Santa Clara, Calif.). They can be adapted for providing at least one substrate in the reaction chamber, and for providing at least one vapor to the reaction chamber, and for reacting the vapor in the reaction chamber so that a material is deposited on the substrate. The instrumentation can be adapted so that the vapor is formed from one or more input gases such as for example two input gases which are mixed before reaction with the hot filament.

At least one hot filament can be used, or a plurality of filaments can be used. The filament can be resistively heated. The filament can be made of materials known in the art for filaments including for example tungsten, tantalum, molybdenum, or rhenium. The filament can be adapted to produce radical species in the vapor and induce thermal reactions in the vapor. The filament can comprise an array or grid of filament wires forming a larger shape.

The geometry and size of the hot filament can be varied for the application but for example a hot filament can be planar in square or rectangular shape. One skilled in the art can scale the size based on, for example, available materials and power supplies. It can have a relatively long length such as for example, a length of at least about five inches, or at least about eight inches. It can have a relatively large area such as for example at least about 18 inches×15 inches, or at least about 39 inches×20 inches, or at least 200 square inches, or at least 250 square inches, or at least 300 square inches, or at least about 500 square inches, or at least about 750 square inches. It can be at least about 3 feet×3 feet, or one meter×one meter. The filament surface area can be sufficiently large to substantially or completely cover the full surface area of the substrate to be subjected to deposition. The filament can comprise a series of individual filaments such as for example 31 filaments spaced about 0.5 inches apart.

The filament diameter can be for example about 50 microns to about 1,000 microns, or about 50 microns to about 500 microns, or about 75 microns to about 175 microns.

The distance between substrate and filament can be for example about 5 mm to about 100 mm, or about 10 mm to about 25 mm, or about 10 mm to about 20 mm.

One skilled in the art can adapt parameters such as spacing between individual filaments and the distance from the filaments to the substrate to control the relative amounts of gaseous precursors arriving at and reacting at the substrate surface. A substrate holder can be used. See for example U.S. Pat. No. 5,424,096. The substrate holder can be adapted to control the temperature of the substrate and in so doing heat and/or cool the substrate as needed with temperature monitoring and feedback. The substrate holder can be also adapted to spatially orient the substrate with respect to the filament as known in the art. For example, the holder can be integrated into a vacuum compatible stage that can rotate or translate the substrate during the growth process while maintaining a vacuum tight seal to the outside environment. The substrate holder can be also adapted as needed to hold one or more individual substrates as known in the art. The dimensions of the vacuum chamber and the substrate holder can be increased to accommodate multiple wafers in a pattern, such as a hexagonal pattern, to maximize yield per run and also deposition uniformity. In one embodiment, a plurality of individual substrates is provided for deposition, and the substrate holder can be adapted accordingly.

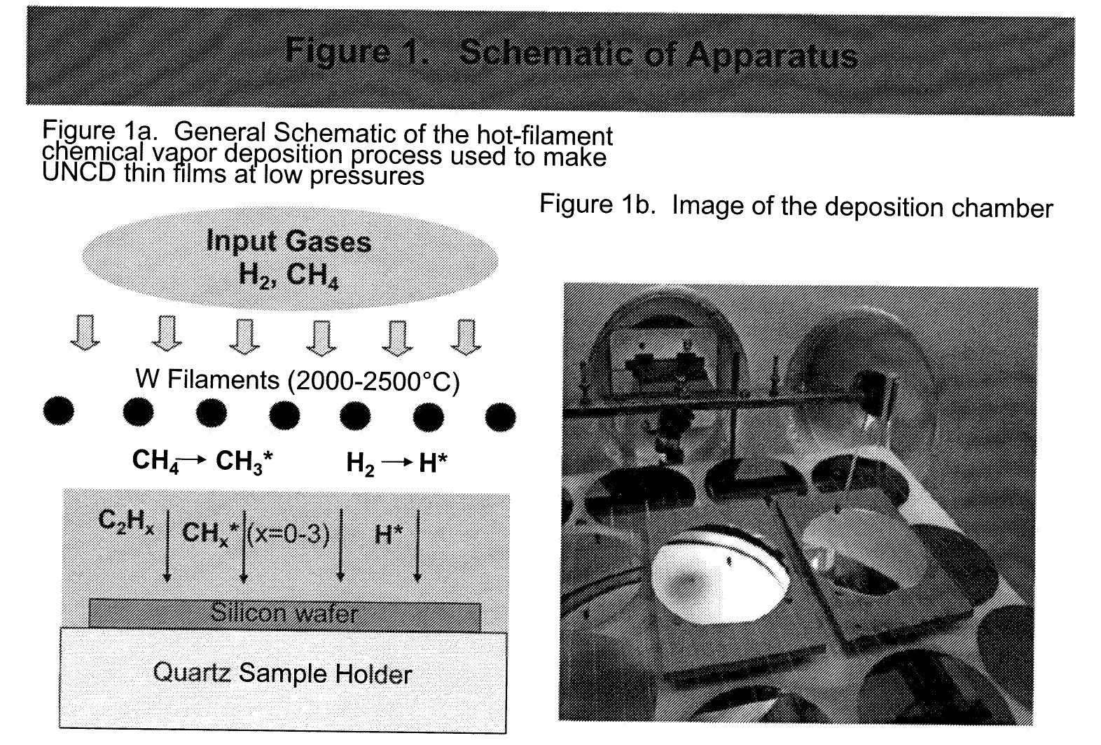

See for example FIGS. 1a and 1b. FIG. 1a illustrates a general schematic showing input gases, hydrogen and methane; filament, tungsten; substrate, silicon wafer; and sample holder, quartz. FIG. 1b illustrates an image of a deposition chamber holding a plurality of substrates. See working examples below.

Instrumentation can be adapted to be free of components for generating microwave plasma.

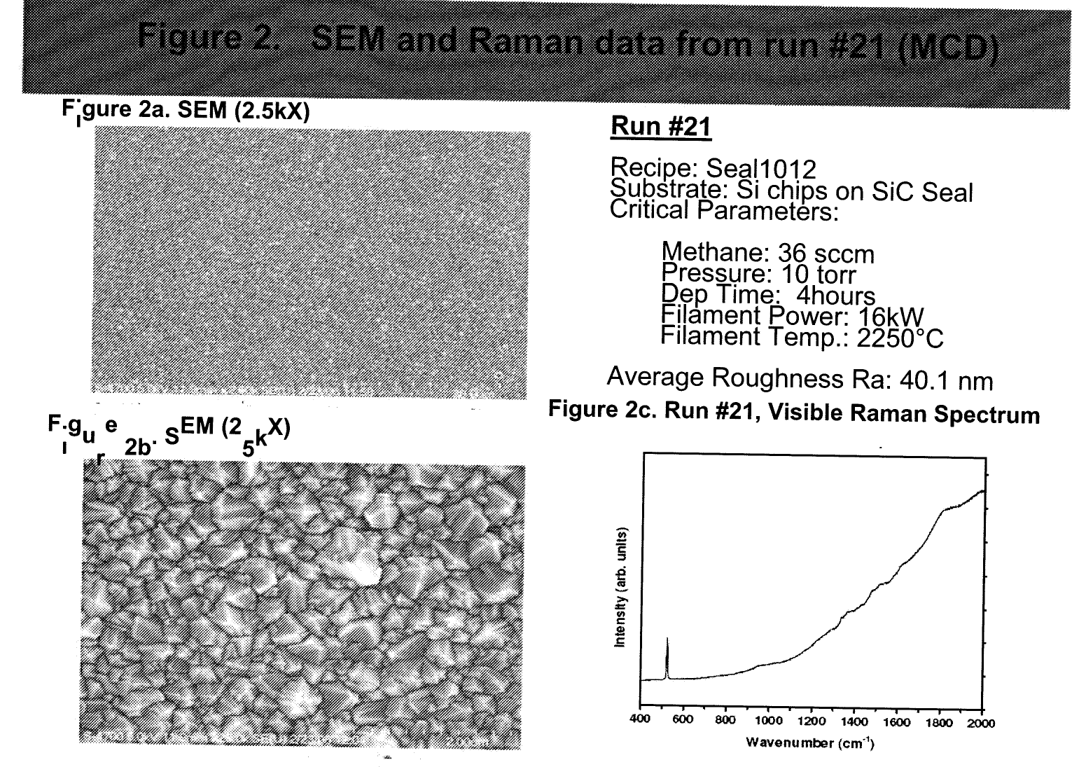

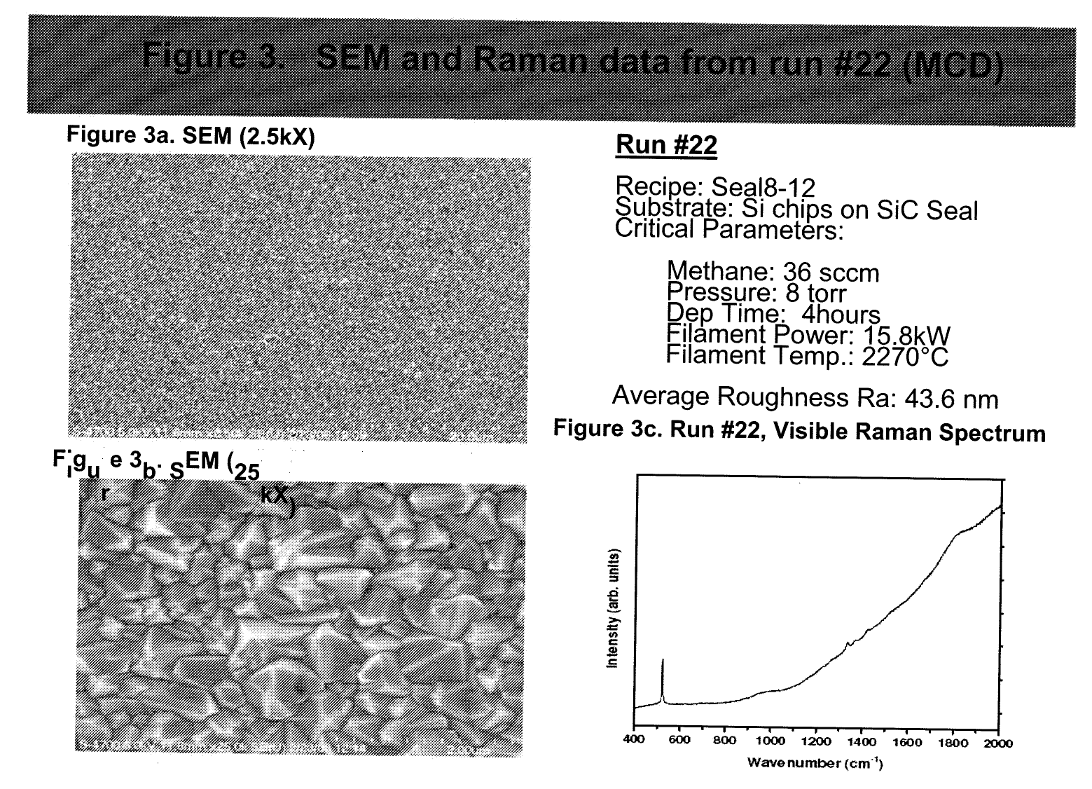

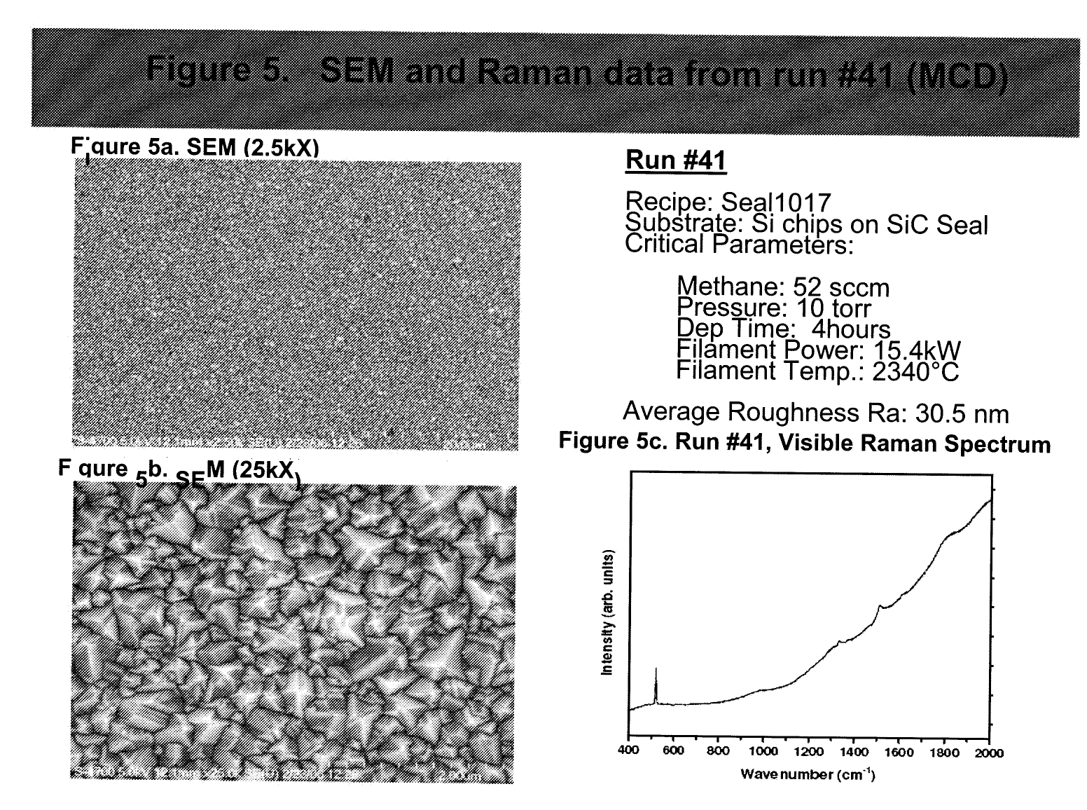

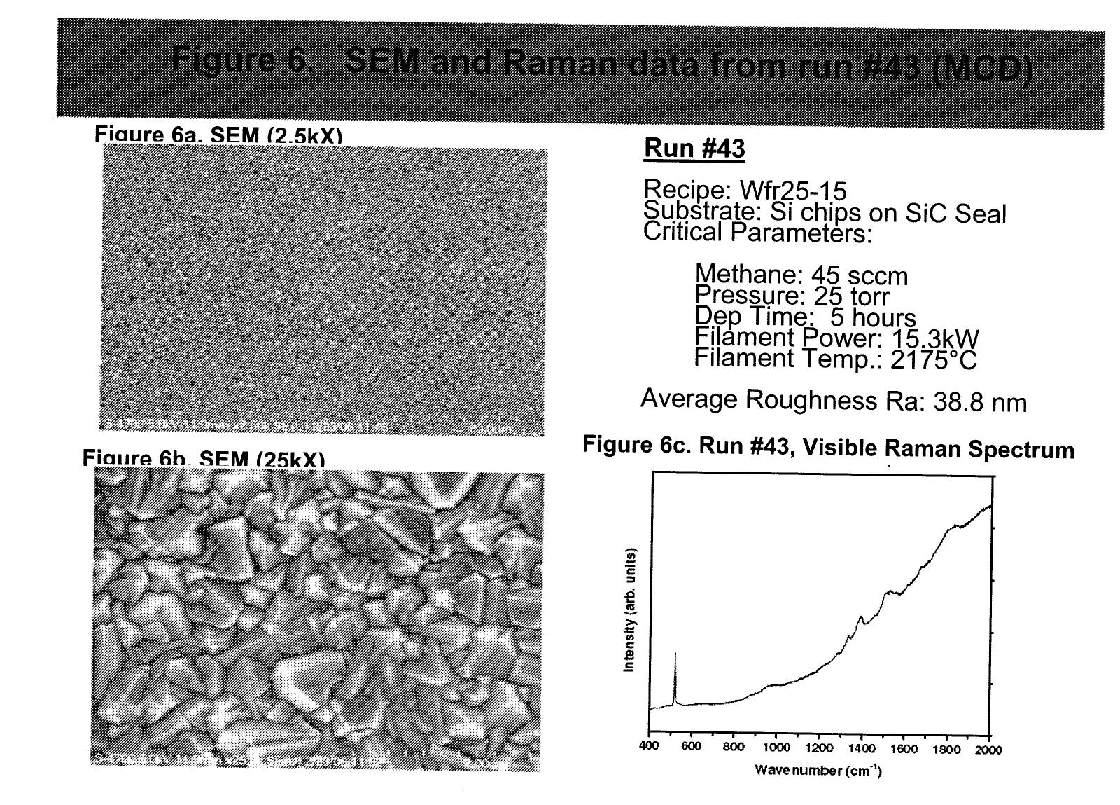

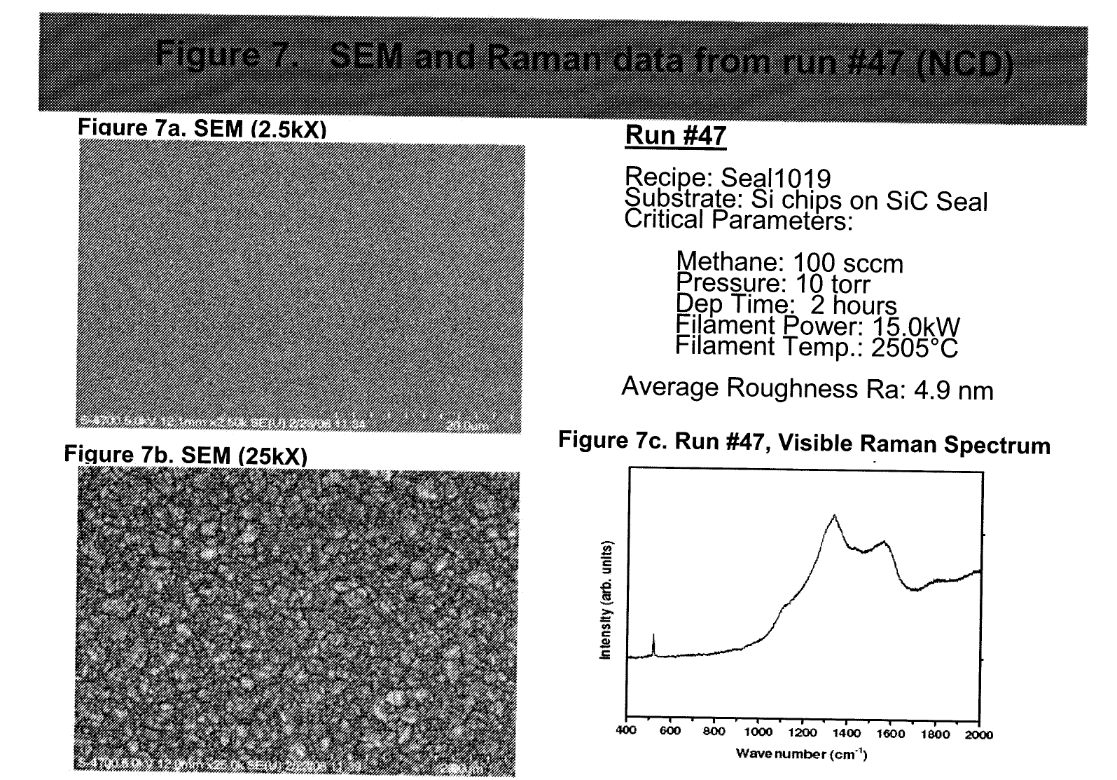

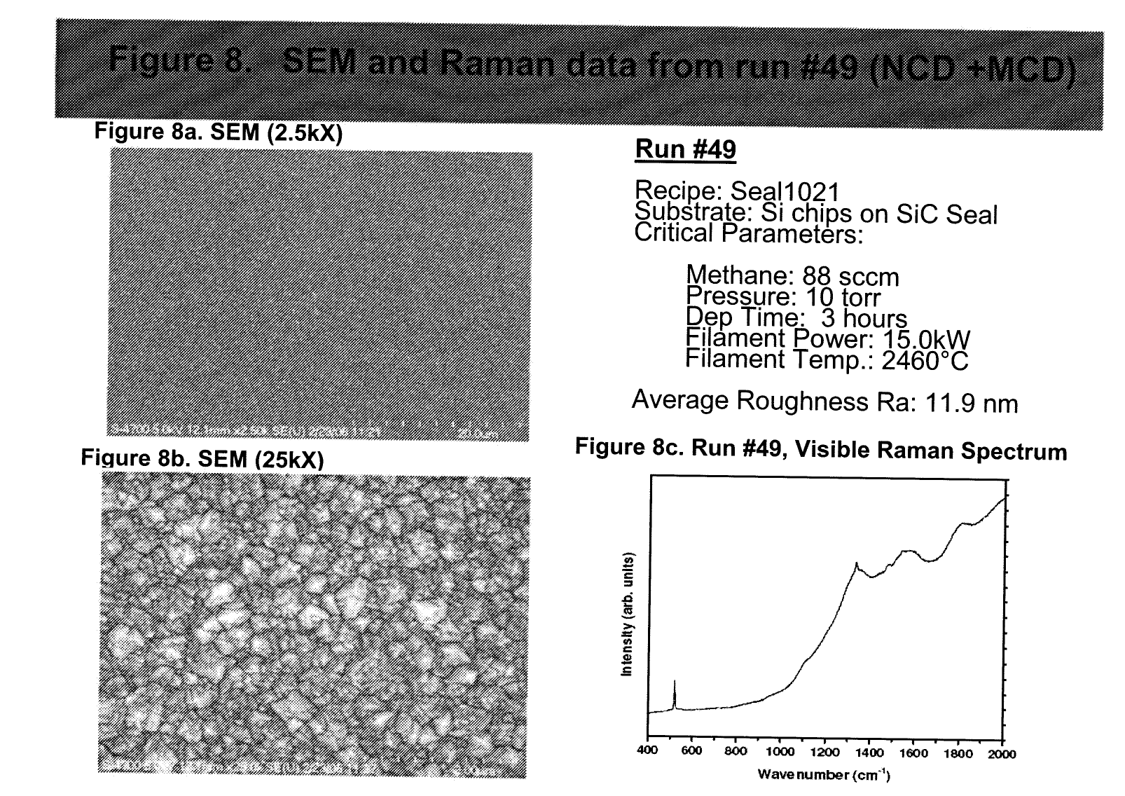

The substrate and the surface thereof can be a variety of solid materials including for example electrically conductive material, semiconductive material, and insulating material. The substrate can be for example a metal, a metal alloy, a ceramic, a glass, a polymer including a high temperature polymer, and the like. Substrates that are known to be useful in diamond coating applications can be used including for example seals and pump seals and mechanical pump seals. Examples include silicon wafers and silicon carbide materials including standard materials available to those skilled in the art. For example, seals can be alpha-sinted SiC mechanical pump seals. For purposes of development, one can use Si chips on a SiC seal, as in FIGS. 2-8, wherein small squares of clean silicon seeded with diamond can be placed on top of older seals, in order to examine the growth of films on the seals without actually consuming the seals.

The substrate can be as smooth as possible so that the diamond film formed on the substrate can be also smooth. For example, substrate roughness (Ra) can be about 1 nm or less including when Si is used as substrate.

The substrate can be treated before subjected to deposition including for example cleaned and abraded.

In addition, for the deposition of diamond thin films, seeding processes can be used in which diamond particles, including microparticles and nanoparticles ranging from microns to nanometers in diameter, can be introduced onto the substrate surface. A variety of methods can be used to do this including for example mechanical abrasion and ultrasonication. The initial stages of diamond growth can proceed via reactions that occur directly on the seed diamond particle surfaces and possibly defects induced by the diamond particles during the seeding process. Also, interlayers such as for example a tungsten interlayer can be used to improve seeding and deposition. See for example Naguib et al., Chemical Physics Letters, 430 (2006), 345-350 which is hereby incorporated by reference in its entirety.

### Process Parameters

The vapor can comprise a plurality of individual components which are fed into the reaction chamber. For example, one component can be a compound comprising carbon which provides carbon for diamond formation. Another component can be hydrogen gas. The vapor can comprise, consist essentially of, or consist of two components which are each fed into the reaction chamber.

In a basic and novel embodiment, the vapor can be substantially free of or completely free of noble and/or inert gas. Gases such as argon and nitrogen can be excluded to the extent they interfere with production of the desired diamond film. One skilled in the art can experiment with these parameters. For example, the amount of noble gas and/or inert gas can be less than about 0.1% with respect to the relative flow rates for the rest of the components, or less than about 0.01%, or less than about 0.001%. The vapor can be completely free of noble and/or inert gas. Examples of noble or inert gases include argon, nitrogen, krypton, xenon, and helium.

The vapor can comprise at least one compound comprising carbon such as for example a hydrocarbon such as for example methane or ethane. Other examples include for example fullerenes, C60, C70, acetone, adamantine, and the like. For an example of use of fullerenes in forming diamond, see U.S. Pat. Nos. 5,209,916, 5,328,676, 5,370,855, 5,620,512, and 5,772,760 (ANL).

The vapor can also comprise hydrogen.

The vapor components can be fed into the reaction chamber at a flow rate and the ratio of the components can be adapted for a specific application. In the chamber, reaction can occur to result in diamond deposition. For example, flow rate can be measured by standard cubic centimeter per minute (sccm). For example, the flow rate of hydrogen can be about 100 sccm to about 5,000 sccm, or about 500 sccm to about 5,000 sccm, or about 1,000 sccm to about 5,000 sccm, or about 2,000 sccm to about 4,000 sccm, or about 3,000 sccm. The flow rate of compound comprising carbon can be for example about 20 sccm to about 250 sccm, or about 50 sccm to about 200 sccm. When two components are fed into the reaction chamber, the relative amounts of two components can be expressed as the ratio or percentage of the two component flow rates, e.g., the flow rate of the compound comprising carbon divided by the flow rate of hydrogen (and multiplied by 100 if expressed by percentage). The amount of the compound comprising carbon can be less than the amount of the other component such as hydrogen. The amount of the compound comprising carbon can be for example about 1% to about 25%, or about 1.5% to about 10%, or about 2.0% to about 6.5%, or about 2.5% to about 3.5%. If more than two components are fed into the reaction chamber, the amount of the compound comprising hydrogen can be expressed with respect to the total amount of the other components.

One can adapt the flow rates for a particular application or desired grain size. See for example U.S. Pat. No. 6,592,839 (ANL).

The reacting step can be carried out at a pressure of less than about 20 torr, or less than about 10 torr, or less than about 8 torr, or less than about 6 torr. The pressure can be for example about 0.5 torr to about 20 torr, or about 1 torr to about 10 torr, or about 3 to about 7 torr, or about 4 to about 6 torr.

The reacting step can be carried out at a substrate temperature of less than about 1,000° C., or less than about 900° C., or less than about 750° C., or less than about 600° C., or less than about 500° C., or less than about 400° C., or about 350° C. or less. The temperature can be for example about 200° C. to about 700° C., or about 300° C. to about 750° C., or about 350° C. to about 750° C., or about 300° C. to about 650° C., or about 300° C. to about 600° C. Substrate temperature can be measured with use of a thermal couple operating on the back side of the substrate site of deposition. Light wire or low mass thermal couples can be used.

The diamond material can be deposited at a deposition rate of at least about 0.1 microns/hour, or at least about 0.3 microns/hour, or at least about 0.5 microns/hour.

The time of deposition can be varied and can be for example less than about 10 h, or less than about 5 h, or less than about 3 h. For example, deposition time can be one minute to 10 h, or two minutes to 5 h, or five minutes to 3 h.

The diamond material can be deposited as a single film over a surface area of at least about 1,500 square mm, or at least about 3,000 square mm, or at least about 5,000 square mm, or at least about 8,000 square mm. This surface area can be increased by using a plurality of substrates.

Diamond can be grown as a single diamond film, wherein a diamond edge is formed which forms a perimeter and a continuous or substantially continuous diamond film can be found within the perimeter. For example, a single diamond film can be substantially a circle. Of course, a series of single diamond films can be grown collectively in parallel in separate areas of the reaction chamber.

The reacting step can be carried out at a filament temperature of at least about 2,350° C., or at least about 2,450° C., or at least about 2,500° C. For example, filament temperature can be about 2,350° C. to about 2,800° C., or about 2,500° C. to about 2,800° C.

Filament power can be adapted for the application and used within instrumental parameters. For example, it can be about 10 to about 20 kW, or about 13 to about 17 kW.

One or more process parameters can be adapted for the substrate selection. For example, use of SiC pump seals as substrates can be executed with use of lower or slightly lower methane/H₂ ratio and lower filament temperature compared to silicon wafer.

Processing can be also adapted to incorporate other elements into the diamond such as for example nitrogen. See for example U.S. Pat. No. 6,793,849 to Carlisle et al. One can also incorporate carbon nanotubes by co-seeding the surface with, for example, diamond and with iron particles. See for example US Patent Publication No. 2006/0222850 to Xiao et al.

While not limited by theory, the processes described herein may relate to control of the production of CHx species, wherein X=0-3, as illustrated in FIG. 1a. Parameters such as, for example, pressure and filament temperature and substrate orientation can be controlled to control the relative amount of these species that participate in the chemistry that takes place on the surface to grow diamond. Under the influence of the hot filament, methane or other compound comprising carbon can decompose into CH₃*, and diatomic hydrogen into H*. The gas ratio can be maintained to maximize the ratio of CH_{X} (X<3) to CH₃ and that the amount of atomic hydrogen at the surface is high enough to prevent formation of graphitic carbon in the crystal grains. This ratio can be adapted based on for example the geometry of the substrate and the growth temperature. It is believed that unexpectedly the low pressure can facilitate diffusion of certain gas molecules from regions near the filaments where they are created to the growth surface. It is believed that unexpectedly the high filament temperatures can lead to generation of a similar distribution of gas-phase molecules compared to conditions generated in an Ar-rich microwave plasma.

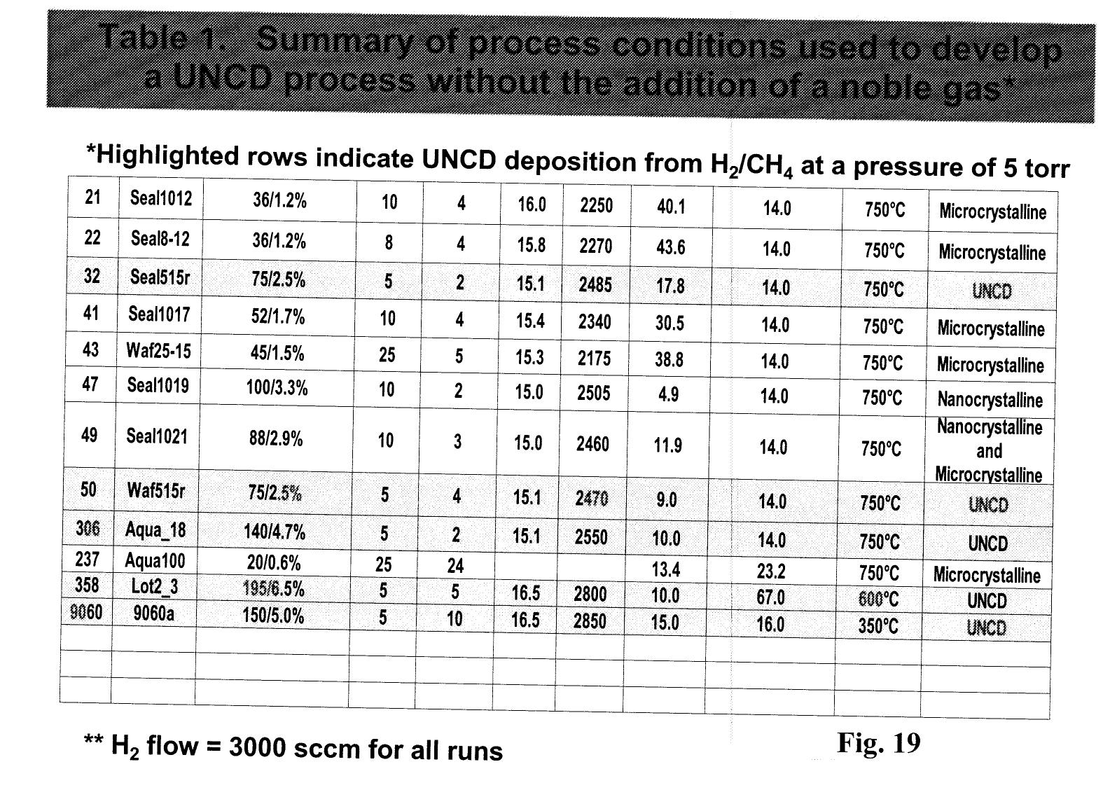

FIG. 19 provides additional process parameters (see more below).

### Characterization of Deposited Material

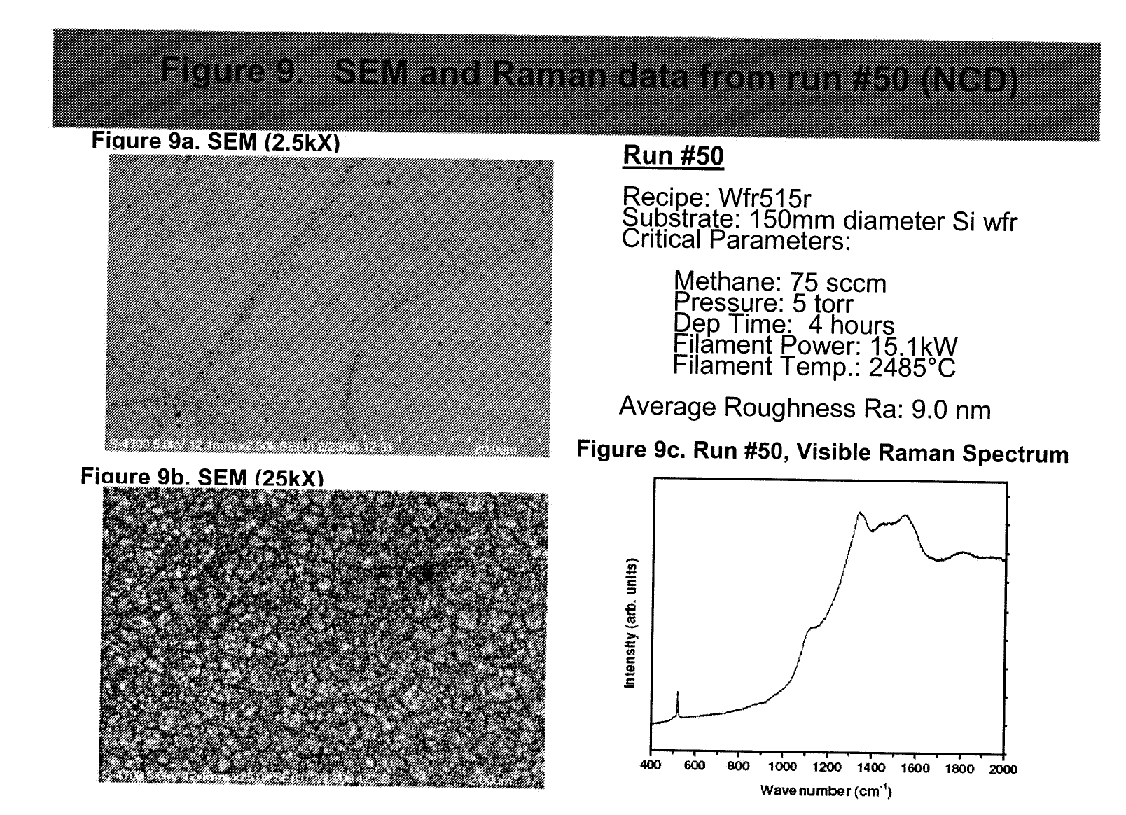

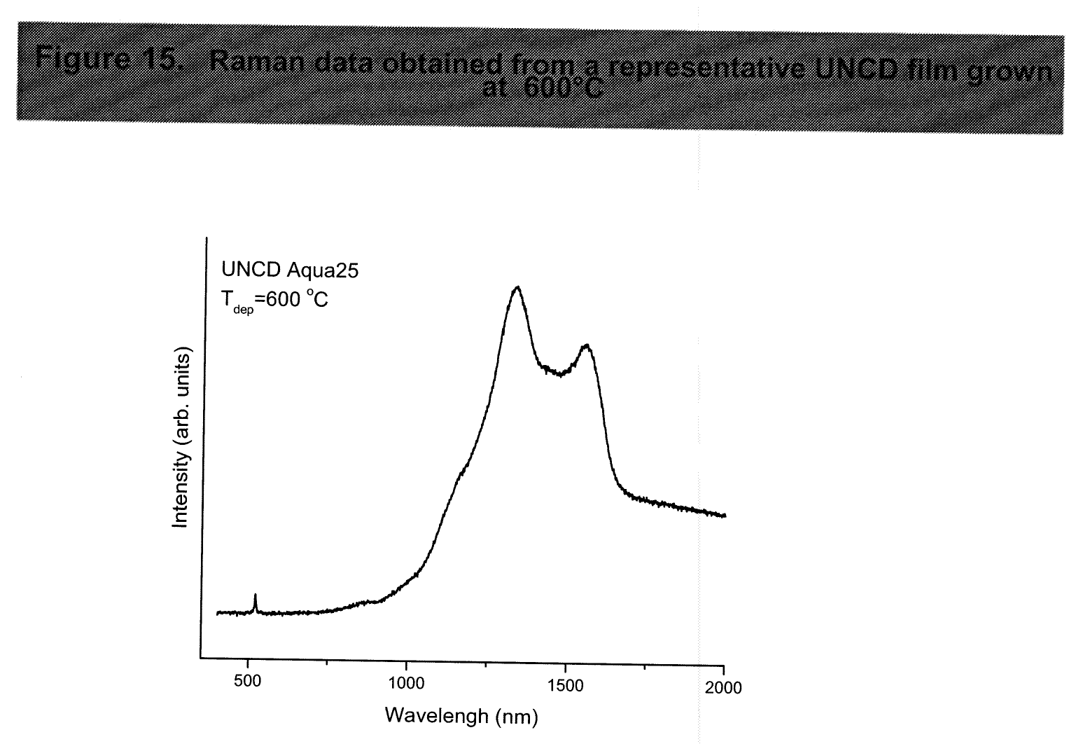

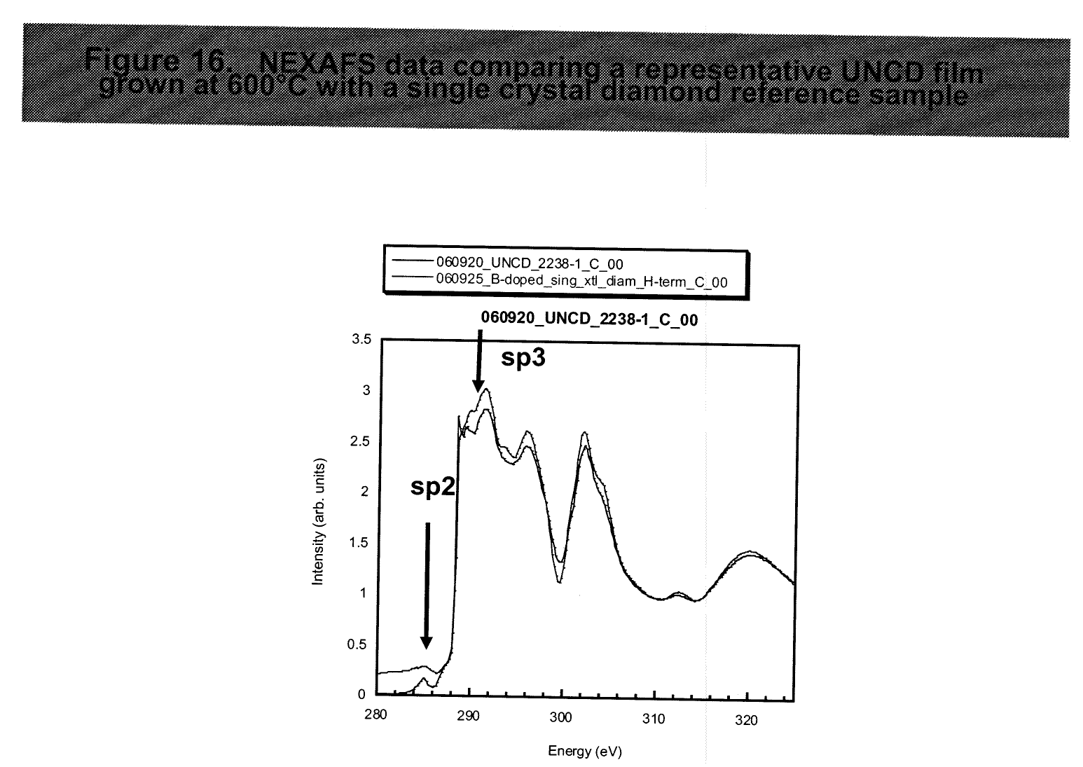

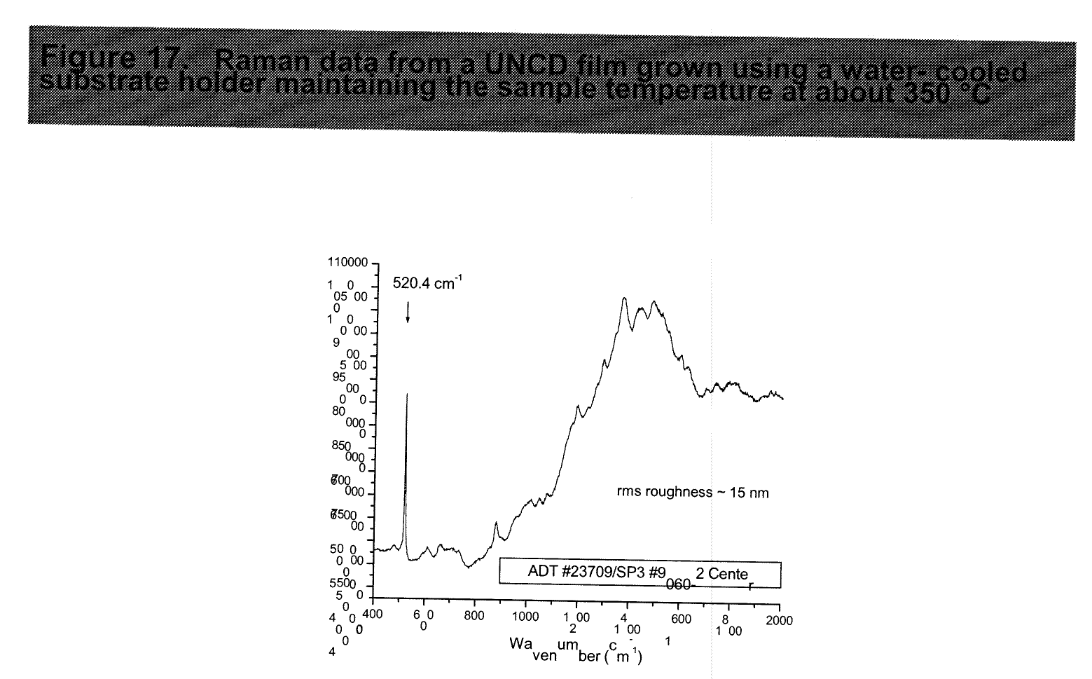

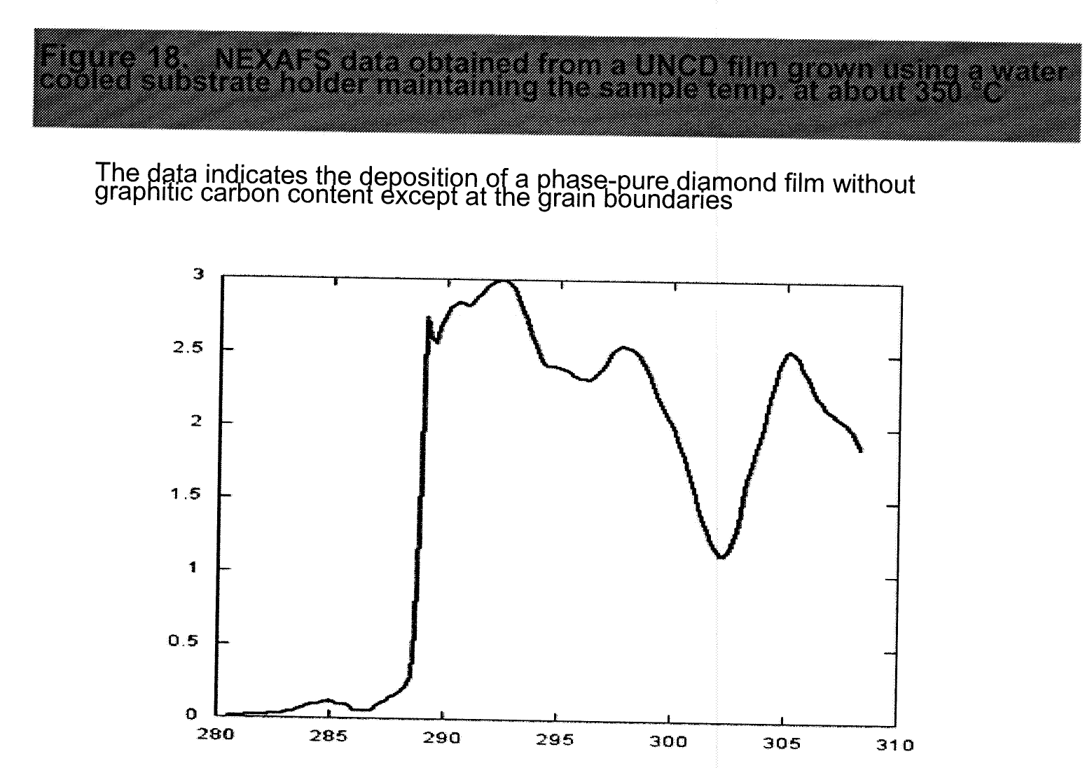

The diamond can be characterized by a variety of methods known in the art to characterize the morphology and structure of diamond films. See FIGS. 1-21. In particular, one can attempt to form diamond having one or more properties which are substantially the same as UNCD prepared by other routes (e.g., microwave plasma CVD) or single crystalline diamond. The diamond can be phase pure UNCD and not a mixture of diamond and graphite phases.

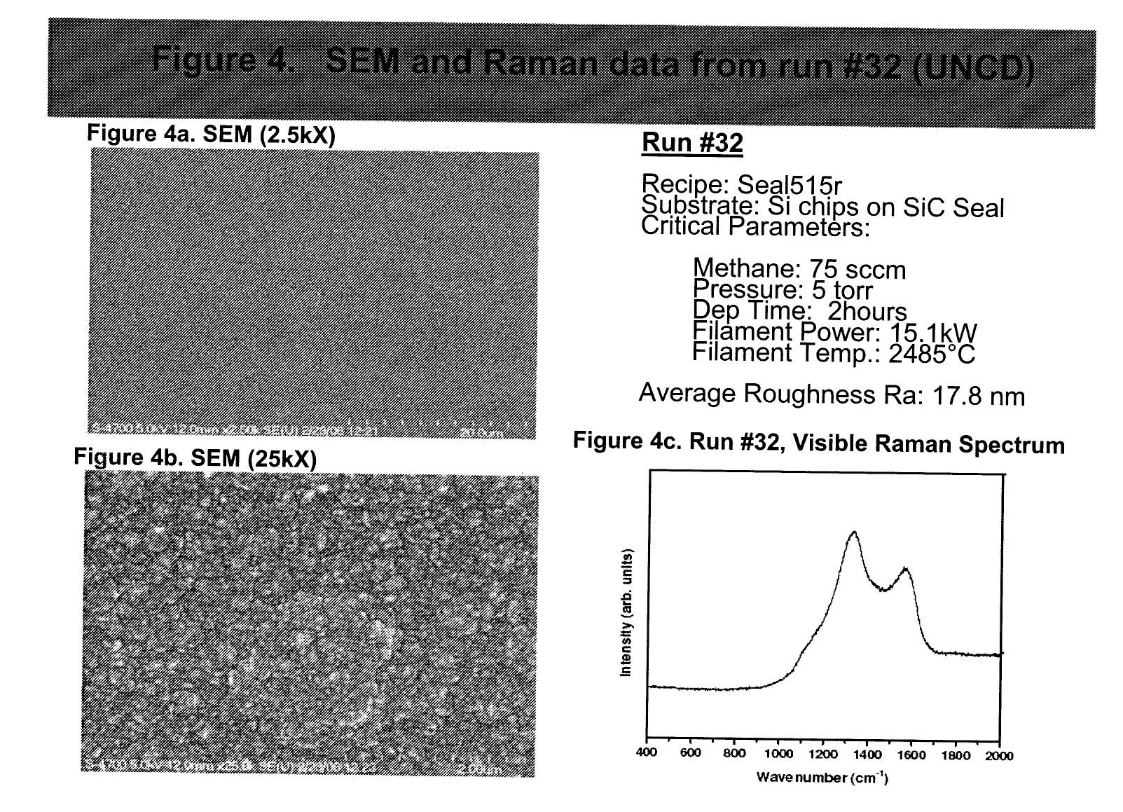

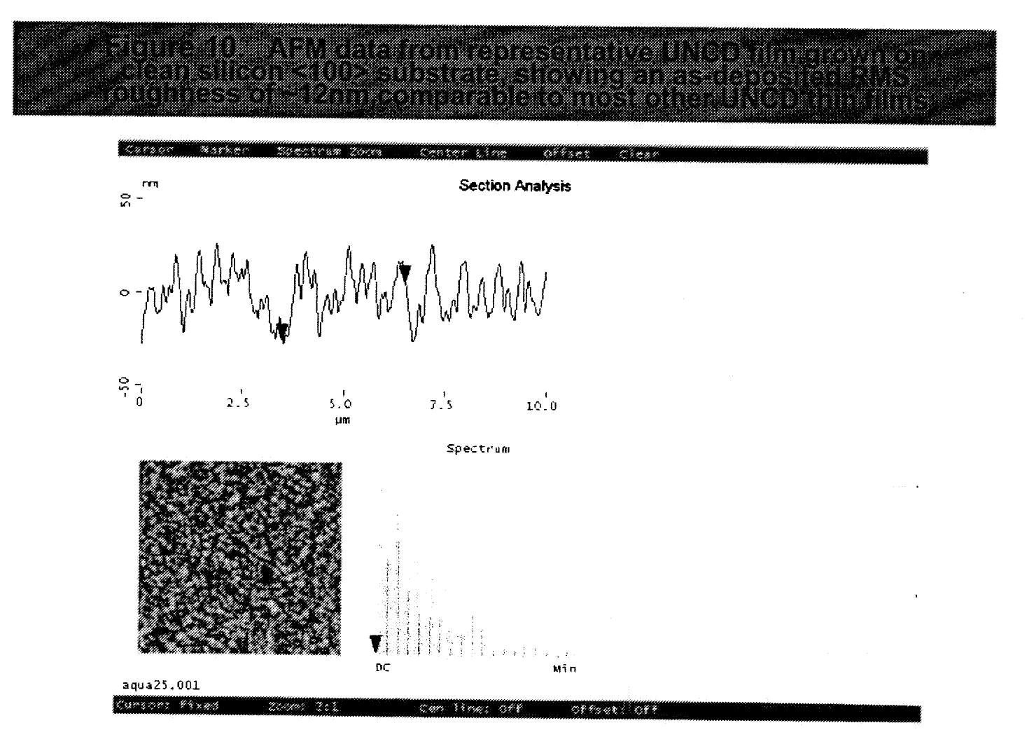

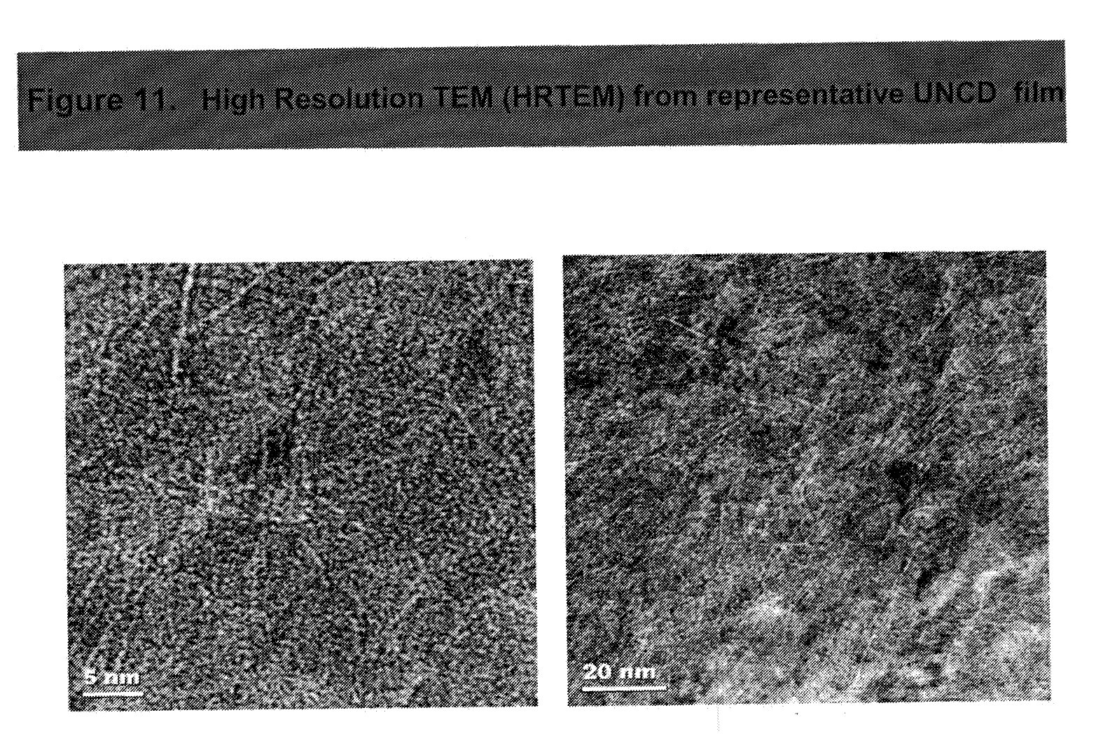

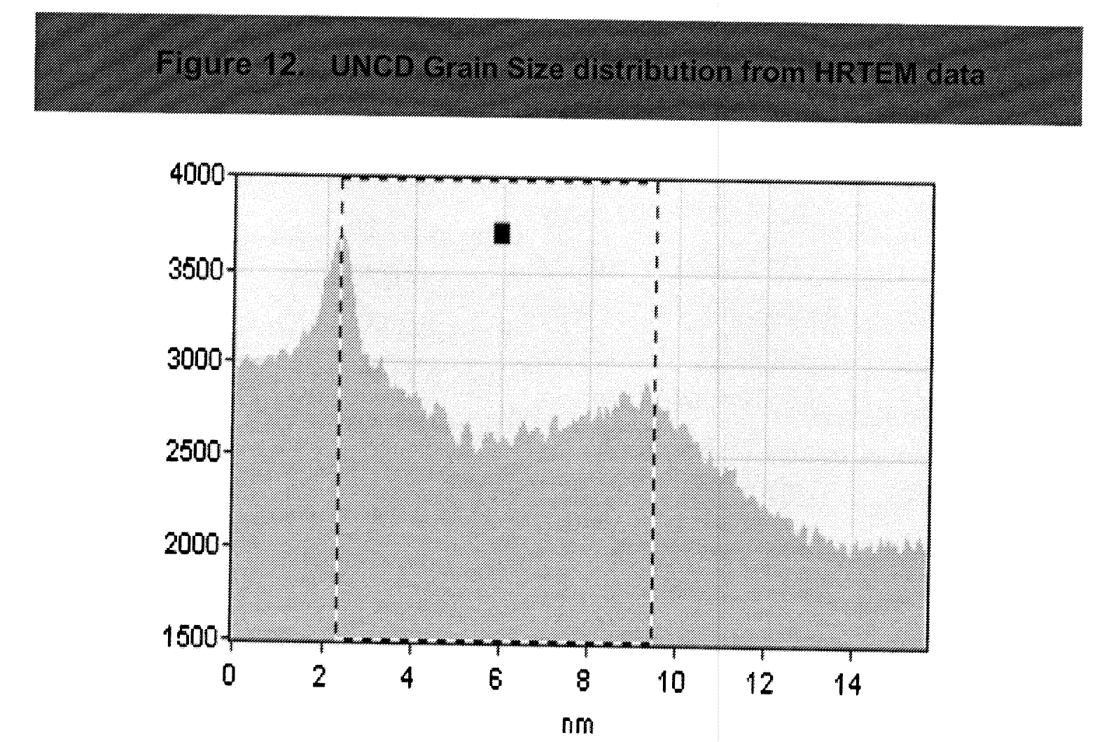

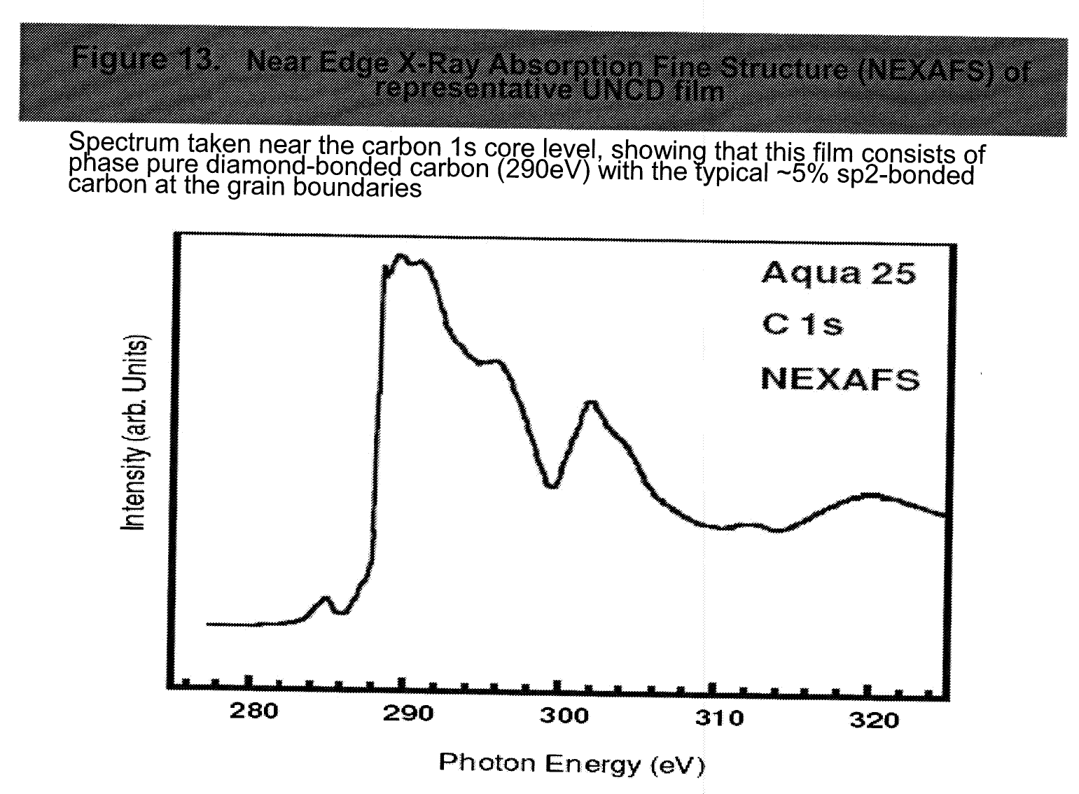

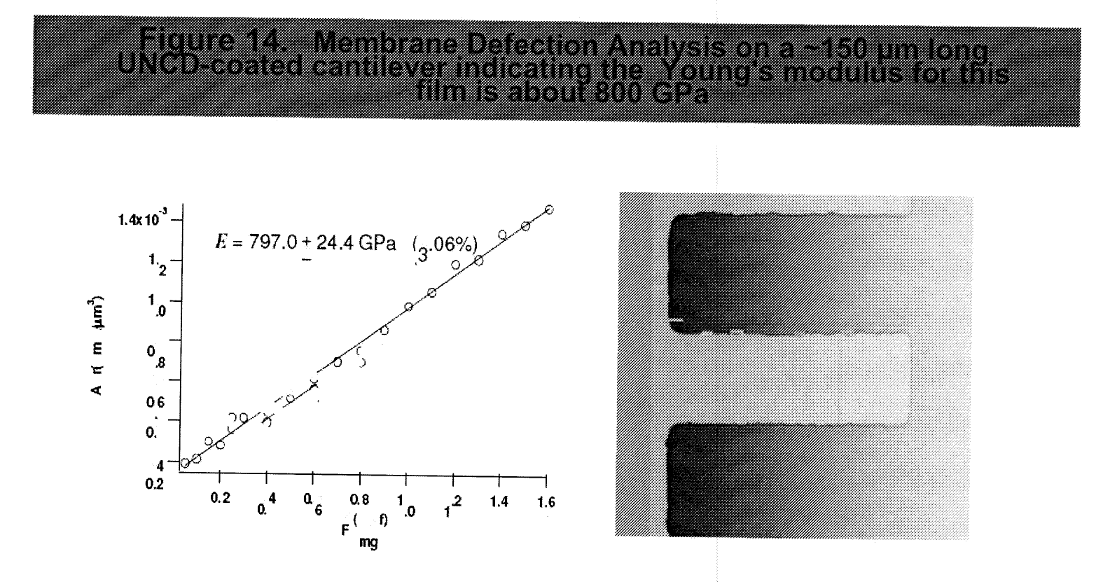

For example, the film can be examined by scanning electron microscopy (SEM) as shown in FIG. 4. In addition, the film can be examined by visible Raman spectroscopy as also shown in FIGS. 4 and 15 and 17. Visible Raman spectroscopy can be carried out with a HeNe laser at 632 nm. UV Raman can be also used. The film can be examined by AFM measurements as shown in FIG. 10. The film can be examined by TEM measurements, including high resolution TEM (HRTEM) as shown in FIGS. 11 and 12. The film can be examined by near edge x-ray absorption fine structure spectroscopy (NEXAFS) as shown in FIGS. 13 and 16 and 18. The film can be examined for mechanical properties including membrane deflection analysis for Young's modulus as shown in FIG. 14.

Film thickness can be for example about 2 microns or less, or about one micron or less, or about 0.1 micron to about 5 microns, or about 0.2 microns to about 3 microns. Film thickness can be measured by SEM analysis of the film in cross-section or by laser interferometry.

Film thickness uniformity can be for example about 10% or less, or about 5% or less, or about 1% or less, over the entire film for a single individual film. Film thickness uniformity can be measured by SEM analysis of the film in cross section or by laser interferometry.

The diamond can be characterized by an average grain size of about 1 nm to about 50 nm, or about 1 nm to about 20 nm. Average grain size can be for example about 1 nm to about 10 nm, or about 2 nm to about 5 nm.

The diamond can be characterized by a grain size distribution wherein for example 90% of particles have a grain size of about 20 nm or less, or about 10 nm or less. The distribution in some cases can be bimodal. In some cases, UNCD can be formed in a form of nanometer-sized grains intermixed with larger diamond grains, with the volume fraction of these larger grains varying from about 8% to 100%.

Furthermore, the diamond can be characterized by atomically abrupt grain boundaries.

The diamond can be characterized by a surface roughness (Ra) of about 30 nm or less, or about 20 nm or less, or about 10 nm or less. No particular limit is present on surface roughness, but for example surface roughness can be at least 1 nm or more, or at least 2 nm or more, or at least 5 nm or more. Surface roughness can be measured by for example atomic force microscopy (see for example FIG. 10) or surface profilometry. The surface roughness can be an as-deposited surface roughness, wherein additional steps to smooth the surface such as polishing have not been carried out. An advantage of smooth surfaces is that they do not need to be by further processes made smooth, which can be expensive. Smoother diamond surfaces are also encouraged by use of smoother substrates. For example, an exemplary pump seal may present a rougher surface than a Si wafer, so the diamond deposited on the pump seal may be accordingly rougher.

The diamond can be characterized by visible Raman spectrum as shown substantially in FIG. 4.

When the diamond is characterized by HRTEM, this method can show, for example, the average grain size and grain size distribution. See for example FIGS. 11 and 12.

When the diamond is characterized by NEXAFS, this method can show, for example, the relative concentration of sp³ and sp²-bonded carbon. See for example FIGS. 13 and 16 and 18. The overall ratio of sp²-bonded carbon and sp³-bonded carbon can be measured. For example, the percentage of sp²-bonded carbon atoms inside the grains can be less than about 10%, or less than about 5%, or less than about 1% as measured by NEXAFS.

The diamond can be characterized by membrane deflection analysis to have Young's modulus of greater than about 700 MPa. See for example FIG. 14. Testing methods are described in for example B. C. Prorok et al., Mechanical Properties of Ultrananocrystalline Diamond Thin Films Relevant to MEMS Devices, Exper. Mech. 43, (3), 256-268 (2003) and references cited therein including 22-24.

Hardness can be greater than about 80 MPa. Hardness can be measured by nanoindentation analysis.

Diamond can be prepared wherein the carbon atoms inside the grains are substantially free of sp² carbon atoms. The carbon atoms which are sp² are substantially only located at the grain boundaries. The grain boundaries also contain carbon atoms that are locally sp³-bonded as well as other intermediate bonding states.

The grain boundaries can be atomically abrupt with little or no graphitic inclusions.

### Applications

Applications of the diamond material include coating on MEMS devices and MEMS devices made with monolithic diamond structures, such as for example AFM probes, RF switches, filters, and oscillators, seal coatings for valves and gaskets and rotating shaft pump seals, biomedical applications including bio-implants (prostheses) and bio-devices (e.g, hermetic coatings for artificial retinas), biosensors, electronics, microelectronic applications, photonic switches, electronic devices including pn junctions, field emission cathodes, and electrochemical electrodes. Low wear tribological applications can be used (wear resistance low friction coatings).

One diamond film cantilever application is described in for example U.S. Pat. No. 6,613,601 (ANL).

Diamond film applications using field emission properties is described in for example U.S. Pat. Nos. 5,902,640 and 6,447,851 (ANL).

Low friction, long wear applications are described in for example U.S. Pat. No. 5,989,511 (ANL).

If desired, the diamond film can be patterned. See for example U.S. Pat. No. 6,811,612 (ANL).

### WORKING EXAMPLES

Non-limiting, exemplary working examples are further provided to illustrate the various embodiments described herein.

The instrument used for diamond deposition was obtained from sp3 Diamond Technologies (Santa Clara), Model 600 with tungsten filament. Filament diameter was about 125 microns.

SEM data was obtained with a Hitachi S-4700-II high resolution SEM.

Visible Raman data was obtained with Renishaw Visible Raman Instrument using a 632 nm laser source.

AFM data was obtained with a Digitial Instruments Nanoscope IV Multimode AFM in ambient air (RH recorded at about 40%) using intermittent-contact mode for imaging, and contact mode for adhesion and friction measurements.

High Resolution TEM (HRTEM) data were obtained with a JEOL 4000EX microscope at 400 kV. HRTEM samples were prepared via mechanical polishing, followed by ion milling at grazing incidence angles. The micrographs were recorded using a 1024×1024 Gatan CCD camera, while the diffraction patterns were recorded photographically.

Near Edge X-ray Absorption Fine Structure (NEXAFS) data were obtained at the Synchotron Radiation Center located at Stoughon, Wis., on the HERMON Beamline, using total electron yield. The spectra were carefully normalized using a reference sample that contained no carbon and an incident flux monitor comprising a Ta grid that had a fresh coating of gold deposited on it.

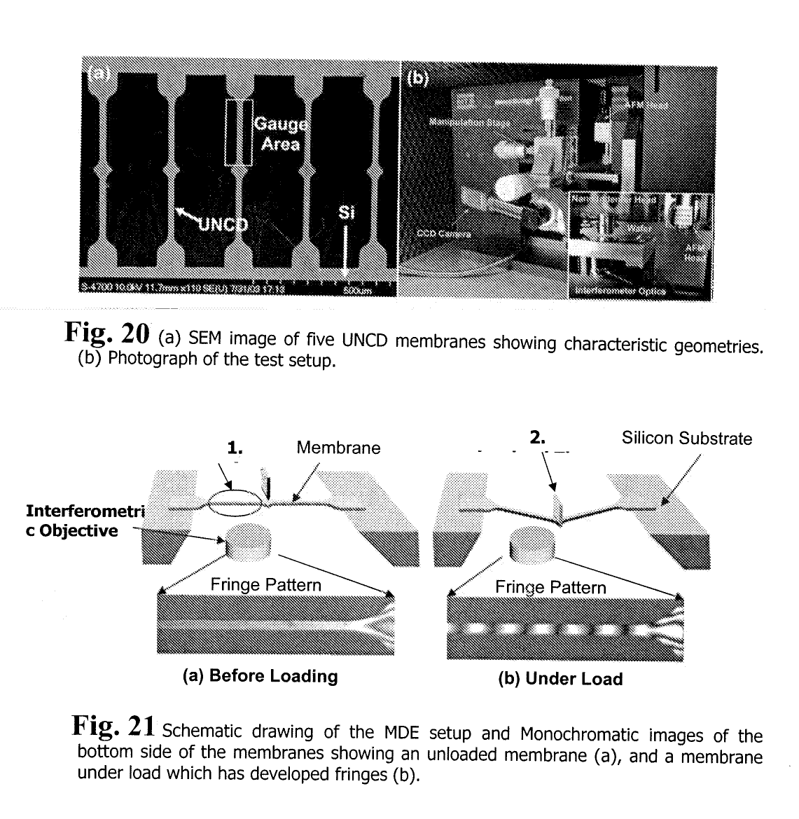

A membrane deflection technique was used to measure the Young's modulus of the films, in which an AFM/nanoindentor was used to deflect fixed-free cantilevered beams of UNCD microfabricated on a silicon wafter. The force-distance curves obtained were fitted to a model mathematical expression for the beam which has the modulus as a free parameter. This is similar to the type of analysis described in for example Espinosa et al., Mechanical Properties of Ultrananocrystalline Diamond Thin Films Relevant to MEMS Devices, Exper. Mech. 43, (3), 256-268 (2003) and references cited therein. In addition, see FIGS. 20 and 21 herein.

FIG. 19 provides a table with the following column headings, as shown for the first entry on the table for run no. 21:

| | |
|---|---|
| Run # | 21 |
| Recipe Name | Seal 1012 |
| Methane flow % rel. to | 36/1.2% |
| H₂ (sccm) | |
| Pressure (torr) | 10 |
| Time (hrs) | 4 |
| Filament Power (kW) | 16.0 |
| Filament Temp. (° C.) | 2,250 |
| R_{A} (nm) | 40.1 |
| Distance substrate to | 14 |
| filaments (mm) | |
| Diamond Type | microcrystalline |

What is claimed is:

1. A method comprising:
providing at least one hot filament chemical vapor deposition reaction chamber,
providing at least one substrate in the reaction chamber,
providing at least one vapor to the reaction chamber, wherein the vapor provided to the reaction chamber comprises (i) a compound comprising carbon, and (ii) hydrogen, and wherein the vapor is substantially free of noble gas and inert gas,
reacting the vapor in the reaction chamber so that a diamond material is deposited on the substrate, wherein the reacting step is carried out at a pressure of less than about 10 torr, and a filament temperature of at least about 2,350° C.

2. The method according to claim 1, wherein a percentage of noble gas and inert gas in the vapor is less than about 0.1% based on relative flow rate.

3. The method according to claim 1, wherein the vapor is completely free of noble gas and inert gas.

4. The method according to claim 1, wherein the vapor provided to the reaction chamber consists essentially of (i) a compound comprising carbon, and (ii) hydrogen gas.

5. The method according to claim 1, wherein the vapor provided to the reaction chamber consists of (i) a compound comprising carbon, and (ii) hydrogen gas.

6. The method according to claim 1, wherein the vapor provided to the reaction chamber comprises the compound comprising carbon in an amount of about 1.5% to about 10% with respect to the hydrogen.

7. The method according to claim 1, wherein the vapor provided to the reaction chamber comprises the compound comprising carbon in an amount of about 2.5% to about 6.5% with respect to the hydrogen.

8. The method according to claim 1, wherein the reacting step is carried out at a pressure of less than about 8 torr.

9. The method according to claim 1, wherein the reacting step is carried out at a pressure of less than about 6 torr.

10. The method according to claim 1, wherein the reacting step is carried out at a substrate temperature of about 900° C. or less.

11. The method according to claim 1, wherein the reacting step is carried out at a substrate temperature of about 600° C. or less.

12. The method according to claim 1, wherein the diamond material is deposited at a rate of at least about 0.1 microns/hour.

13. The method according to claim 1, wherein the diamond material is deposited at a rate of at least about 0.3 microns/hour.

14. The method according to claim 1, wherein the diamond material is deposited over as a single film over a surface area of at least about 1,500 square mm.

15. The method according to claim 1, wherein the diamond material is deposited over a surface area of at least about 8,000 square mm.

16. The method according to claim 1, wherein the reacting step is carried out at a filament temperature of at least about 2,450° C.

17. The method according to claim 1, wherein the reacting step is carried out at a filament temperature of at least about 2,500° C.

18. The method according to claim 1, wherein the reaction chamber comprises a filament array which presents a source of heat and reactive gas species that is planar in geometry.

19. The method according to claim 1, wherein the reaction chamber comprises a filament which is planar and has an area relative to the substrate of at least one.

20. The method according to claim 1, wherein the reaction chamber further comprises a substrate holder adapted to cool the substrate.

21. The method according to claim 1, wherein the reaction chamber further comprises a substrate holder adapted to spatially orient the substrate with respect to the filament.

22. The method according to claim 1, wherein the diamond is characterized by an average grain size of about 50 nm or less.

23. The method according to claim 1, wherein the diamond is characterized by an average grain size of about 20 nm or less.

24. The method according to claim 1, wherein the diamond is characterized by grain size distribution which is bimodal and comprises grains less than about 20 nm in size mixed with grains that are greater than about 100 nm in size with the volume fraction of small to large sized grains at least about 90%.

25. The method according to claim 1, wherein the diamond as deposited is characterized by surface roughness average of about 20 nm or less.

26. The method according to claim 1, wherein the diamond as deposited is characterized by surface roughness average of about 10 nm or less.

27. The method according to claim 1, wherein the diamond is characterized by HRTEM to have an average grain size of about 10 nm or less.

28. The method according to claim 1, wherein the diamond is characterized by NEXAFS to have an sp²-bonded carbon content of less than 5%.

29. The method according to claim 1, wherein the diamond has a Young's modulus of at least 700 MPa.

30. The method according to claim 1, the diamond has an average grain size less than 10 nm, a roughness average of less than 20 nm, the diamond is characterized by NEXAFS to have an sp2-bonded carbon content of less than 5%, and the diamond is characterized by membrane deflection analysis to have a Young's modulus of at least 700 MPa.

31. A method comprising:
providing at least one hot filament chemical vapor deposition reaction chamber,
providing at least one substrate in the reaction chamber,
providing at least one vapor to the reaction chamber, wherein the vapor provided to the reaction chamber comprises (i) a compound comprising carbon, and (ii) hydrogen, and wherein the vapor is substantially free of noble gas and inert gas,
reacting the vapor in the reaction chamber so that a diamond material is deposited on the substrate, wherein the reacting step is carried out at a pressure and filament temperature to produce diamond material characterized by:
an average grain size of about 10 nm or less,
a roughness average for the as-deposited film of about 20 nm or less, and
a ratio of sp²- to sp³-bonded carbon of about 5% or less.

32. The method according to claim 31, wherein a diamond material is formed as a single film having an area of at least 1,500 square mm.

33. The method according to claim 31, wherein a diamond material is formed as a single film having an area of at least 8,000 square mm.

34. The method according to claim 31, wherein a diamond film is formed having a film thickness uniformity of less than about 10%.

35. The method according to claim 31, wherein the roughness average is less than about 10 nm.

36. The method according to claim 31, wherein the ratio of sp²- to sp³-bonded carbon of about 5% or less.

37. The method according to claim 31, wherein the diamond has a Young's modulus of at least about 700 MPa.

38. The method according to claim 31, wherein the diamond has a hardness of at least about 80 MPa.

39. The method according to claim 31, wherein the reacting step is carried out at a pressure of about 10 torr or less, and a filament temperature of about 2,350° C. or more.

40. The method according to claim 31, wherein the reacting step is carried out at a pressure of about 6 torr or less, and a filament temperature of about 2,450° C. or more.

41. A method comprising:
providing at least one hot filament chemical vapor deposition reaction chamber,
providing at least one substrate in the reaction chamber, the substrate having a surface area of at least 8,000 square mm,
providing at least one vapor to the reaction chamber, wherein the vapor provided to the reaction chamber comprises (i) a compound comprising carbon, and (ii) hydrogen, and wherein the vapor is substantially free of noble gas and inert gas,
reacting the vapor in the reaction chamber so that a diamond material is deposited on the substrate, wherein the reacting step is carried out at a pressure of less than about 10 torr, and a filament temperature of at least about 2350° C., wherein diamond material characterized by: an average grain size of about 10 nm or less, a roughness average for the as-deposited film of about 20 nm or less, and a ratio of sp²- to sp³-bonded carbon of about 5% or less.

42. The method according to claim 41, wherein at least two substrates are present.

43. The method according to claim 41, wherein a diamond material is formed as at least two single films each having an area of at least 8,000 square mm.

44. The method according to claim 41, wherein a diamond film is formed having a film thickness uniformity of less than about 10%.

45. The method according to claim 41, wherein the roughness average is less than about 10 nm.

46. The method according to claim 41, wherein the ratio of sp2- to sp3-bonded carbon of about 1% or less.

47. The method according to claim 41, wherein the diamond has a Young's modulus of at least about 700 MPa.

48. The method according to claim 41, wherein the diamond has a hardness of at least about 80 MPa.

49. The method according to claim 41, wherein the reading step is carried out at a pressure of about 8 torr or less, and a filament temperature of about 2,450° C. or more.

50. The method according to claim 41, wherein the reacting step is carried out at a pressure of about 6 torr or less, and a filament temperature of about 2,450° C. or more, and a reaction time of about 5 h or less.

51. A method comprising:
providing at least one hot filament chemical vapor deposition reaction chamber comprising a hot filament,
providing at least one substrate in the reaction chamber, wherein the substrate is held by a substrate holder which is adapted to heat and cool the substrate and orient the substrate position with respect to the hot filament,
providing flow of vapor to the reaction chamber, wherein the vapor provided to the reaction chamber comprises (i) a compound comprising carbon, and (ii) hydrogen, and wherein the vapor is substantially free of noble gas and inert gas,
reacting the vapor in the reaction chamber so that a diamond material is deposited on the substrate, wherein the reacting step is carried out at a pressure of less than about 10 torr, and a filament temperature of at least about 2,350° C., and wherein the reacting step is carried out at a substrate temperature of about 600° C. or less.

52. The method according to claim 51, wherein at least two substrates are present.

53. The method according to claim 51, wherein a diamond material is formed as at least two single films each having an area of at least 8,000 square mm.

54. The method according to claim 51, wherein a diamond film is formed having a film thickness uniformity of less than about 10%.

55. The method according to claim 51, wherein the roughness average is less than about 10 nm.

56. The method according to claim 51, wherein the ratio of sp2- to sp3-bonded carbon of about 5% or less.

57. The method according to claim 51, wherein the diamond has a Young's modulus of at least about 700 MPa.

58. The method according to claim 51, wherein the diamond has a hardness of at least about 80 MPa.

59. The method according to claim 51, wherein the reacting step is carried out at a pressure of about 8 torr or less, and a filament temperature of about 2,450° C. or more.

60. The method according to claim 51, wherein the reacting step is carried out at a pressure of about 6 torr or less, and a filament temperature of about 2,450° C. or more.

61. A method comprising:
providing at least one hot filament chemical vapor deposition reaction chamber,
providing at least one substrate in the reaction chamber,
providing at least one vapor to the reaction chamber, wherein the vapor provided to the reaction chamber comprises (i) a compound comprising carbon, and (ii) hydrogen, and wherein the vapor is substantially free of noble gas and inert gas,
reacting the vapor in the reaction chamber so that a diamond material comprising ultrananocrystalline diamond is deposited on the substrate, wherein the reacting step is carried out at a pressure of less than about 10 torr, and a filament temperature of at least about 2,350° C.

62. The method according to claim 61, wherein the deposition is carried out with a substrate temperature of about 200° C. to about 700° C.

63. The method according to claim 61, wherein the deposition is carried out with a substrate temperature of about 300° C. to about 650° C.

64. An article comprising:
a substrate,
at least one single diamond film disposed on the substrate, wherein the area of the single diamond film is at least 8,000 square mm and the single diamond film is characterized by an average grain size of about 10 nm or less, a roughness average for the as-deposited film of about 20 nm or less, and a ratio of sp2- to sp3-bonded carbon of about 5% or less.

65. An article prepared by the method of claims 1, 31, 41, 51, or 61.
